(19) United States
(12) Patent Application Publication
(10) Pub. No.: US 2015/0129283 A1
(43) Pub. Date: May 14, 2015

(54) PROPERTIES OF PRINTED CONDUCTIVE TRACKS

(71) Applicant: NATIONAL RESEARCH COUNCIL OF CANADA, Ottawa (CA)

(72) Inventors: Gaozhi XIAO, Ottawa (CA); Zhiyi ZHANG, Ottawa (CA); Hiroshi FUKUTANI, Limoges (CA); Ye TAO, Ottawa (CA)

(73) Assignee: NATIONAL RESEARCH COUNCIL OF CANADA, Ottawa (CA)

(21) Appl. No.: 14/536,019

(22) Filed: Nov. 7, 2014

Related U.S. Application Data
(60) Provisional application No. 61/901,651, filed on Nov. 8, 2013.

(51) Int. Cl. H05K 1/02; H05K 3/22; H05K 3/12

(52) U.S. Cl. CPC H05K 1/0201; H05K 3/1241; H05K 3/22; H05K 3/227; H05K 1/02; H05K 1/0213
USPC 174/250; 219/251

(57) ABSTRACT

A process for improving a property of a conductive ink track on a substrate involves applying heat and pressure above a glass transition temperature of the binder to a conductive ink track deposited on a first surface of a substrate, while maintaining a second surface of the substrate at a temperature below a glass transition temperature, a melting temperature or a degradation temperature of the substrate. In particular, electrical conductivity of the track is improved. The process is particularly useful for producing electronic devices, for example electrical circuits, sensors, antennae (e.g. RFID antennae), touch switches and smart drug packaging on various substrates

### CROSS-REFERENCE TO RELATED APPLICATIONS

This application claims the benefit of U.S. Provisional Patent Application Ser. No. 61/901,651 filed Nov. 8, 2013, the entire contents of which are herein incorporated by reference.

### FIELD

This application relates to printable electronics.

### BACKGROUND

Printed conductive tracks have found many applications including electrical circuits, sensors, and antennas. The conductive inks used for the printing purpose usually comprise three main components: metal particles/flakes, binders, and solvents (Crumpton 2011; Dorfman 2005; Dorfman 2010). The metal particles/flakes provide the electrical properties required, the binders bind the particles/flakes together and provide the tracks with adequate inherent mechanical properties and the adhesion to the substrate, the solvents are mainly used to make the ink printable.

After printing, the printed tracks go through a drying/curing process as suggested by the ink suppliers in order to remove the solvents. A fast drying/curing process, which is required by production lines, not only requires fairly high temperature, but also leaves a large amount of microstructural voids inside the printed tracks (as illustrated in FIG. 1). FIG. 1 shows a SEM cross-section picture of a conductive track printed using a Xerox ink and processed under the condition suggested by Xerox. The picture clearly shows the existence of many micro voids/binder-filled pockets inside the printed track and the poor contact among the silver particles/flakes. According to the law of mixing, those voids/binder-filled pockets result in printed tracks with poor electrical (high electrical resistance) and thermal conductivities as the volumetric fraction of the particles/flakes decreases with the increase in the amount of voids and binder-filled pockets. The fast drying of solvents could also weaken the adhesion between the printed tracks and the substrate, sometimes causing the lift-off of the printed tracks.

In US patent application publication US 2010/0231672 (Joyce 2010), calendering was proposed as a post-curing method to improve the electrical conductivity of the printed tracks. Calendering is a two-roll hot pressing process. After drying/curing, the printed conductive tracks are hot pressed by the calenders. There is one significant drawback of this method, i.e. the temperature claimed is below 110° C. As many binder materials used in the conductive inks have glass transition temperatures (T_{g}) either around 110° C. or higher, the disclosed calendering process is treating hard materials. This method is not very efficient (as seen from the results presented in the publication) and the method can cause damage to the printed tracks.

A mechanical pressing technique for post-curing of printed conductive tracks has been proposed (Yoshida 2011). This is again a hot pressing technique. In Yoshida 2011, the authors touched the densification and reorientation of the particles in the printed conductive tracks. The pressing technique used a temperature less than 120° C. and a pressure over 100 MPa (14,504 psi). This pressure is too high for high speed industrial manufacturing. In addition, this hot pressing technique takes 30 seconds, which is too long for high throughput production.

There remains a need for a method of improving properties of conductive tracks, which is amenable to high throughput manufacturing processes.

### SUMMARY

There is provided a process for improving a property of a conductive ink track on a substrate, the method comprising: applying heat and pressure to a conductive ink track deposited on a first surface of a substrate, the conductive ink comprising conductive particles and a binder, the heat providing a temperature above a glass transition temperature of the binder; and, maintaining a second surface of the substrate at a temperature below a glass transition temperature, a melting temperature or a degradation temperature of the substrate while the heat is applied to the conductive ink track on the first surface of the substrate.

There is further provided a printed electronic device produced by the process.

In embodiments, the improvement to the property may be one or more of increased electrical conductivity, increased thermal conductivity, increased strength, or increased bonding performance to external attachments. Increased electrical or thermal conductivity may be viewed as decreased electrical or thermal resistivity, respectively.

The process is particularly useful for producing electronic devices, for example electrical circuits, sensors, antennae (e.g. RFID antennae), touch switches and smart drug packaging on various substrates

Further features will be described or will become apparent in the course of the following detailed description. It should be understood that each feature described herein may be utilized in any combination with any one or more of the other described features, and that each feature does not necessarily rely on the presence of another feature except where evident to one of skill in the art.

### BRIEF DESCRIPTION OF THE DRAWINGS

For clearer understanding, preferred embodiments will now be described in detail by way of example, with reference to the accompanying drawings, in which:

FIG. 1 depicts a typical scanning electron microscope (SEM) cross-section picture of a printed conductive track processed using standard condition suggested by the ink supplier;

FIG. 2 depicts a pulsed heat/pressure densification process implemented using a flat-bed press;

FIG. 3 depicts a pulsed heat/pressure densification process implemented using a roll-to-roll arrangement;

FIG. 4 depicts a continuous system for processing printed conductive ink tracks including a pulsed heat/pressure densification process implemented using a roll-to-roll arrangement;

FIG. 5A depicts SEM pictures of cross-sections of various printed tracks processed using standard curing procedures, where the top image is for DuPont 5029 ink and the bottom image is for XEROX's XRCC Lab384 ink;

FIG. 5B depicts SEM pictures of cross-sections of various printed tracks processed using the pulsed heat/pressure densification process of the present invention, where the top image is for DuPont 5029 ink and the bottom image is for XEROX's XRCC Lab384 ink; and,

FIG. 6 depicts a printed RFID loop antenna design.

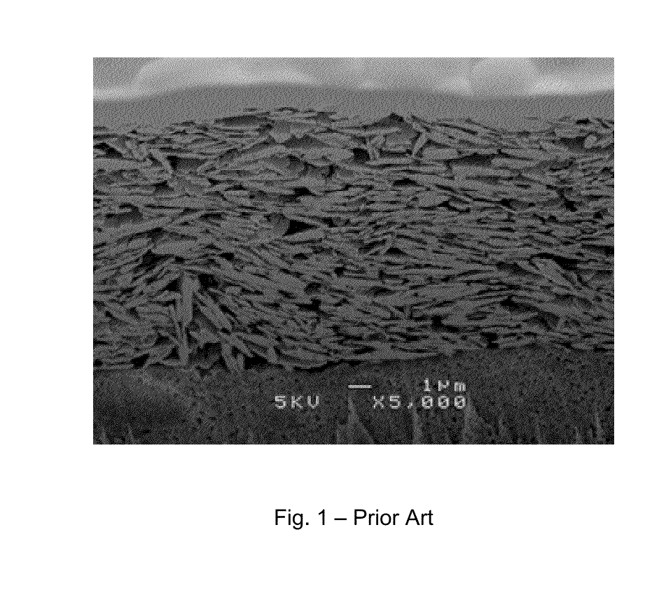

### DETAILED DESCRIPTION

Conductive inks are generally known in the art and many suitable inks for use in the present process are commercially available. Conductive inks for printed circuits generally comprise three main components: conductive particles, a binder and a solvent. The conductive particles provide electrical properties, the binder binds the particles together and provides the tracks with adequate mechanical properties and adhesion to the substrate and the solvent is mainly used to make the ink printable. The conductive ink may be provided in any suitable physical form, for example liquids or pastes.

The conductive particles may be any suitable shape, for example flakes, spheres, rods, cones, plates or irregularly-shaped. Flakes are preferred. Flakes are particles where two lateral dimensions are substantially larger (e.g. at least about 10 times larger, preferably about 100 times larger) than a third dimension (i.e. thickness) of the particle. The particles preferably have an average particle size in a range of about 1-100 microns, preferably about 1-50 microns, although particle sizes of less than 1 micron may be used in some products. The particles preferably have a particle size distribution in a range of about 10-50% of the average particle size. Conductive particles may be conductive metals, conductive non-metals or mixtures thereof. Some examples of conductive metal particles include Ag, Au, Cu, Pt, Pd, Ru, Ni, Al, any alloys thereof or any mixture thereof. Some examples of conductive non-metals include carbon particles, carbon nanotubes, graphenes or any mixture thereof. Silver (Ag) is preferred. The conductive particles preferably comprise 30-95 wt % of the ink based on total weight of the ink.

The binder may be any suitable organic or inorganic polymer or resin that is able to bind the conductive particles together and adhere with sufficient strength to the substrate. The binder preferably comprises an organic polymer or resin, for example polyacrylic acid, a polyacrylate, a phenoxy polymer, a urethane polymer, polyethylene imine, polyvinyl pyrrolidone, carboxymethylcellulose, polyvinyl alcohol, a polyester, among others. The binder may comprise homopolymer, copolymer, terpolymer or polymer blends. The solvent is preferably an organic solvent, for example toluene, benzene, methyl propyl ketone, n-propyl acetate, n-butyl acetate, isobutyl acetate, and mixtures thereof. Other additives, for example plasticizers, microbicides, etc. may be included. The non-conductive components of the ink are preferably present in the ink composition in an amount of about 5-70 wt % with the binder generally in a range of about 15-35 wt %.

The substrate may be any suitable substrate for the purpose to which the conductive ink is being put. Substrates include, for example polyethylene terephthalate (PET), polyolefin (e.g. silica-filled polyolefin (Teslin™) polydimethylsiloxane (PDMS), polystyrene, polycarbonate, polyimide, textiles (e.g. cellulosic textiles) among others.

Depositing the ink on a substrate may be accomplished by any suitable method, for example, inkjet printing, flexography printing (e.g. stamps), gravure printing, screen printing, off-set printing, airbrushing, typesetting, or any other method. After deposition, the ink may be dried or cured according to standard procedures, for example allowing the ink to dry in ambient conditions or heating the ink for a relatively long period of time (e.g. up to 5 minutes) to evaporate the solvent, before applying the present process. Or, the ink deposited on the substrate may be subjected to the present process immediately after deposition, or the solvents in the ink deposited being partially evaporated and then subjected to the present process.

The present process results in densification of the microstructure of the conductive ink tracks on the first surface of the substrate. The process may also serve to flatten the substrate in comparison to the substrate before the process was performed. A flatter substrate may have a more uniform thickness and may be substantially more planar with fewer bends and/or warps.

To densify the microstructure of conductive ink tracks efficiently, the binders in the inks should be softened (similar to the processing of plastics) while applying pressure. The temperature applied to the conductive ink trace is above a glass transition temperature (T_{g}) of the binder. The temperature is preferably in a range of about ±30° C. of the melting temperature (Tₘ) of the binder, i.e. greater than 30° C. below the melting temperature and less than 30° C. above the melting temperature of the binder. The temperature is preferably in a range of about 5-200° C. above the T_{g} of the binder, more preferably about 25-150° C. above the T_{g} of the binder, even more preferably about 50-120° C. above the T_{g} of the binder. The pressure applied to the conductive ink trace is preferably in a range of about 10-2000 psi, more preferably about 100-1000 psi. The heat and pressure are preferably applied for a short period of time, preferably for a duration in a range of about 0.01-5 seconds, for example about 2 seconds. The heat and pressure may be applied in one pulse for a short period of time, or may be applied in two or more pulses each for short time periods of time. Each application of heat and pressure may be at the same or different temperature and/or pressure for the same or different length of time. The time delay between applications of heat and pressure may be sufficient to cool the substrate in preparation for the next pulse of heat and pressure. The delay time is preferably on the same order of magnitude as the pulse time, for example about 0.01-5 seconds. As heat transfer takes time, the use of heat/pressure pulses reduces the possibility of deforming or damaging the substrate.

Most polymer substrates used for printed conductive tracks also soften or degrade in the temperature range of the present process. Therefore, a long time at high temperature and pressure is likely to deform or damage the substrate. This may be why the prior art (Joyce 2010; Yoshida 2011) limited the processing temperature to lower than 120° C. However, polymer materials are poor conductors. Therefore, integrity of the substrate may be maintained if the heat/pressure treatment is done for a short period of time. The exact pulse length (or time) depends on the particular substrate and ink used. In addition, due to the softening of the binder during the process, the pressure required for the densification of the printed tracks can be decreased accordingly. Integrity of the substrate may also be maintained by applying the heat only to the first surface of the substrate on which the conductive trace is deposited. Thus, the temperature at the second surface of the substrate may be maintained below a glass transition temperature, a melting temperature or a degradation temperature of the substrate while the heat is applied to the conductive ink track on the first surface of the substrate. Any suitable method for applying the heat and pressure in this manner may be implemented. Two embodiments are described as follows.

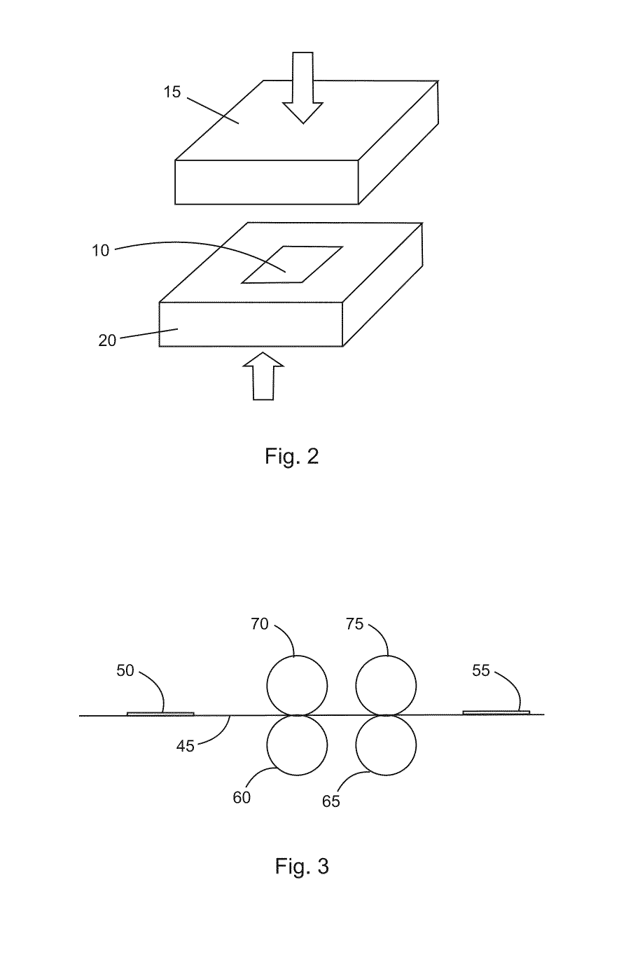

A first approach is to use a flat-bed press as illustrated in FIG. 2. A second approach is to use a roll-to-roll arrangement as illustrated in FIG. 3, which can be adopted by R2R production lines as a continuous process.

FIG. 2 illustrates the use of the pulsed heat/pressure process to treat a printed device with a flat-bed press. A hot press 15 is raised to a desired temperature (e.g. in a range of 5 to 200° C. above the glass transition temperature of the binder in the ink). A device 10 printed with conductive ink is dried/cured (partially or completely) and placed on a cold press 20 maintained at a temperature lower than the glass transition temperature, melting temperature or degradation temperature of the substrate of the device 10. The device 10 is pressed between the hot press 15 and the cold press 20 under a desired pressure (e.g. in a range of 10-2000 psi) for a desired period of time (e.g. 0.01-5 seconds). If needed, the pressing step is repeated for a number of times required. The treated device 10 may then be removed from the cold press 20 and is ready to be processed further.

FIG. 3 illustrates the use of the pulsed heat/pressure process to densify printed devices 50, 55 with a roll-to-roll arrangement. The devices are dried/cured using conditions suggested by the ink supplier and placed on a moving guide 45 (e.g. a conveyor belt or ramp) and pass between the pairs of rolls 60, 70 and 65, 75. Device 50 is shown on the guide 45 prior to passing between the pairs of rolls 60, 70 and 65, 75, while device 55 is shown on the guide 45 after passing between the rolls 60, 70 and 65, 75. Hot rolls 70, 75 are at a desired processing temperature above the glass transition temperature of the binder in the ink, while cold rolls 60, 65 are maintained at a temperature lower than the glass transition temperature, melting temperature or degradation temperature of the substrates of the devices 50, 55. The pressure applied by each pair of rolls 60, 70 and 65, 75 is set to a desired value (e.g. in a range of 10-2000 psi), and the pressing time is set by the speed of the guide to a desired value (e.g. in a range of 0.01-5 seconds). A continuous line of devices may be pressed between each pair of rolls 60, 70 and 65, 75 and the treated devices removed from the guide 45 ready for further processing. Although two pairs of rolls are shown in FIG. 3, one pair or more pairs of rolls may be used if desired or required.

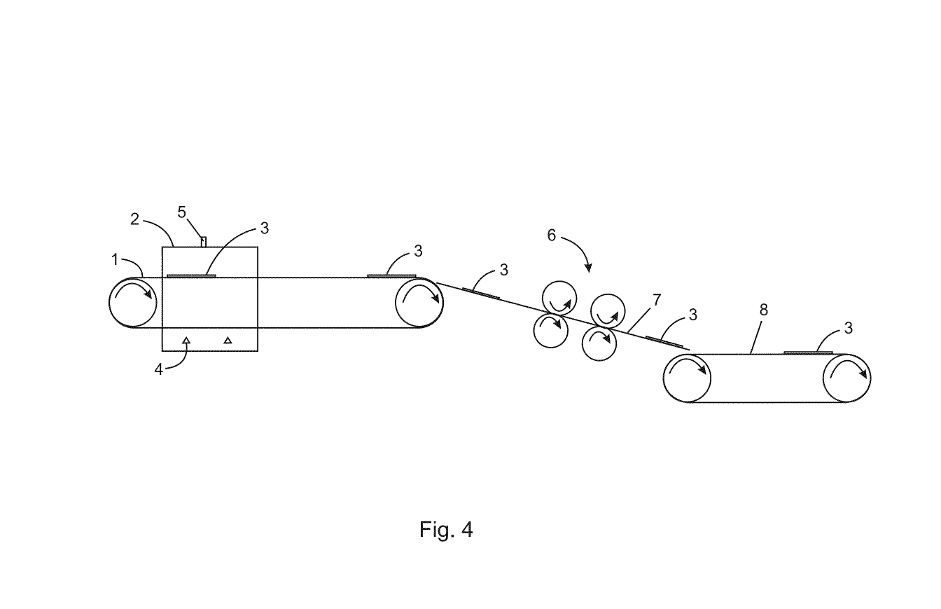

The arrangement illustrated in FIG. 3 can be integrated with a drying/curing process of the ink to form a continuous system and process, as illustrated in FIG. 4. The continuous system illustrated in FIG. 4 may involve a mesh conveyor 1 for transporting a printed device 3 through an oven 2 equipped with a heating source 4 and a vent 5. The device 3 is transported to a guide 7 (e.g. a ramp) that passes between hot and cold press rolls of thermal-mechanical pulsing rolls 6. After pressing, the device 3 slides down the guide 7 between the hot and cold press rolls to land on a second conveyor 8 to be carried to the next processing step. The drying/curing process is done in the oven 2 set at the temperature recommended by the ink supplier or slightly lower (for example 0-60° C. lower) for a time recommended by the ink supplier or shorter (for example 0.5-5 minutes for the total drying time depending on the ink used). The pulsed heat/pressure densification process occurs between the hot and cold press rolls of the thermal-mechanical pulsing rolls 6, after which the device 3 cools down to ambient temperature and passes on to the next stage of work.

### EXAMPLES

### Example 1

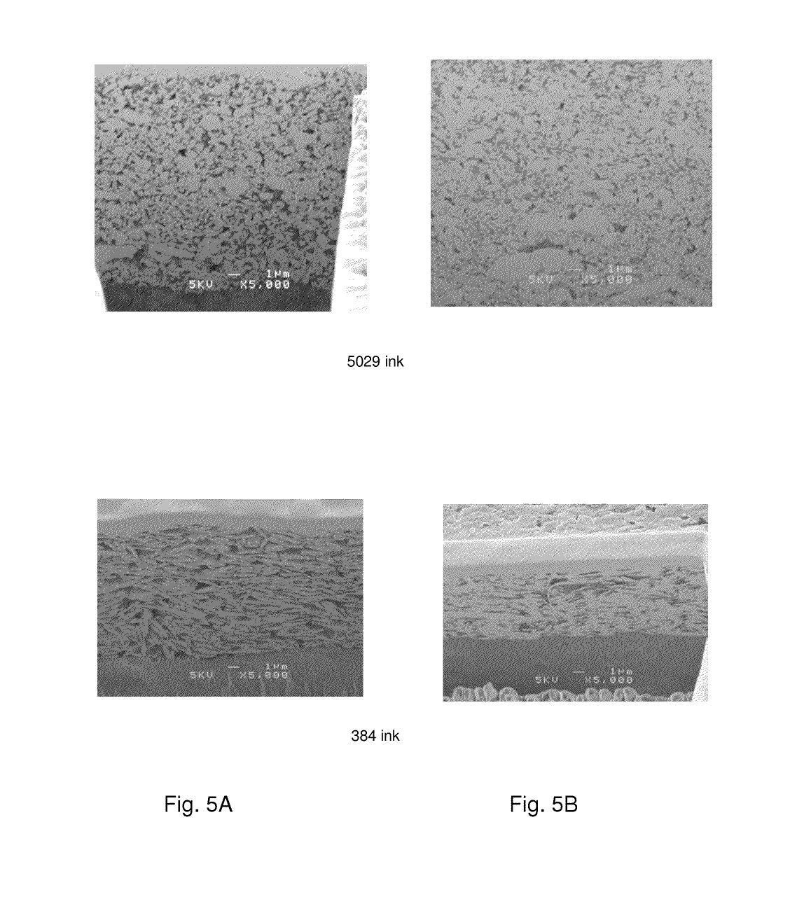

Two types of conductive inks are used in this example. One is DuPont 5029 ink, the other is XEROX's XRCC Lab384 ink. Both inks were screen printed on Teslin™ substrates. The printed conductive tracks were heat/pressure treated at a temperature of 170° C. and a pressure of 950 psi for 2 seconds using the flat-bed press method. The SEM pictures of the printed tracks before and after the treatment are shown in FIGS. 5A and 5B. As it can be seen, the pulsed heat/pressure densification process gives a much more densely packed microstructure for the processed tracks.

### Example 2

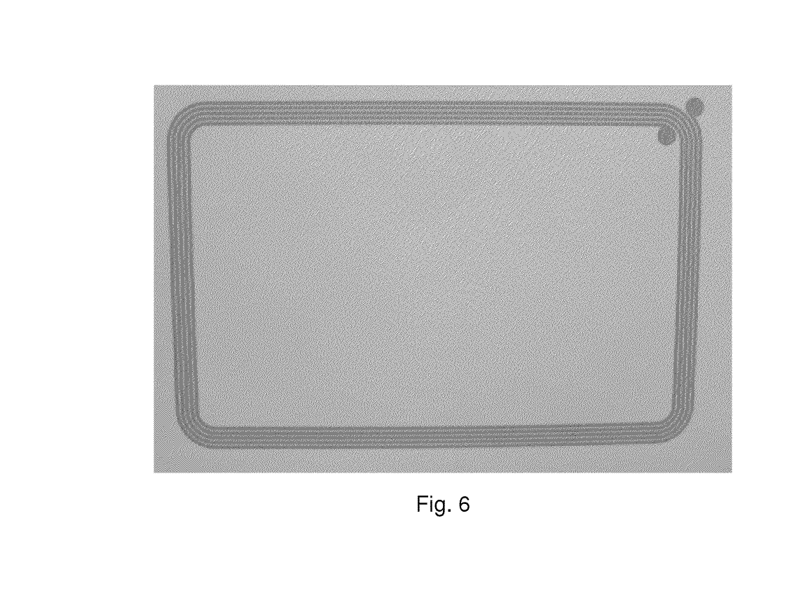

DuPont 5029 was printed on Teslin™ to form RFID antennae having a configuration as shown in FIG. 6. Six different antenna designs were printed. For each design, one antenna was firstly processed using standard conditions recommended by the manufacturer and then was processed using the pulsed heat/pressure densification process.

In a first pulsed heat/pressure densification process, loop antennas of design 1 to design 5 were processed on a flat-bed press as depicted in FIG. 2 with two heat/pressure pulses. Each pulse lasted 2 seconds with one minute time lapse between then. A pressure of about 950 psi and a temperature of about 160° C. were applied. Direct current (DC) electrical resistance for each of the samples dried using the standard conditions suggested by DuPont was measured before and after the heat/pressure treatment. The results are shown in Table 1. It is evident from Table 1 that the pulsed heat/pressure process induces the electric resistance of the samples to decrease by about 3 times. In other words, the conductivity of the samples is increased by about 3 times by the pulsed heat/pressure process.

TABLE 1

| | Resistance (Ohms) | |
|---|---|---|
| Sample | Standard Condition | Pulsed Heat/Pressure |
| Design 1 | 43.1 | 12.7 |
| Design 2 | 41.4 | 14.6 |
| Design 3 | 46.8 | 16.4 |
| Design 4 | 32.8 | 11.3 |
| Design 5 | 37.8 | 12.3 |

In a second pulsed heat/pressure densification process, loop antennas were processed on a flat-bed press as depicted in FIG. 2 with one heat/pressure pulse. The pressure was not optimized but was in a range of 100-700 psi. The temperature was about 250° C., which is more than 100° C. higher than the glass transition temperature of the ink binders and significantly higher than the softening temperature of the substrates.

Direct current (DC) electrical resistance for each of the samples was measured and compared to the DC electrical resistance of the same antennae before the heat/pressure process but after processing using the standard conditions suggested by the ink supplier. The results are shown in Table 2. The results clearly demonstrate the effectiveness of the pulsed heat/pressure process. After the process, there is no visually observable change to the substrates.

TABLE 2

| | | | Resistance (Ohms) | |
|---|---|---|---|---|
| | | | Standard | Pulsed |
| Sample | Ink | Substrate | Condition | Heat/Pressure |
| Design 1 | 1 | Teslin ™ | 43 | 14 |
| Design 6 | 1 | Teslin ™ | 46 | 13 |

### REFERENCES

The contents of the entirety of each of which are incorporated by this reference.
Crumpton J C, Dorfman J R. (2011) Polymer thick film silver electrode composition for use as a plating link. United States Patent Publication US 2011/0068011 published Mar. 24, 2011.
Dorfman J R. (2005) Thick film conductor compositions for use in membrane switch applications. U.S. Pat. No. 6,939,484 issued Sep. 6, 2005.
Dorfman J R (2010) High conductivity polymer thick film silver conductor composition for use in RFID and other applications. U.S. Pat. No. 7,857,998 issued Dec. 28, 2010.
Joyce M, Fleming P D, Pankar S P. (2010) Method of Improving the Electrical Conductivity of a Conductive Ink Trace Pattern and System Therefor. United States Patent Application Publication US 2010/0231672 published Sep. 16, 2010.
Yoshida M, Suemori K, Uemura S, Hoshino S. (2011) Printed Electrode for All-Printed Polymer Diode. Japanese Journal of Applied Physics. 50, 04DK16.

The novel features will become apparent to those of skill in the art upon examination of the description. It should be understood, however, that the scope of the claims should not be limited by the embodiments, but should be given the broadest interpretation consistent with the wording of the claims and the specification as a whole.

1. A process for improving a property of a conductive ink track on a substrate, the method comprising: applying heat and pressure to a conductive ink track deposited on a first surface of a substrate, the conductive ink comprising conductive particles and a binder, the heat providing a temperature above a glass transition temperature of the binder; and, maintaining a second surface of the substrate at a temperature below a glass transition temperature, a melting temperature or a degradation temperature of the substrate while the heat is applied to the conductive ink track on the first surface of the substrate.

2. The process according to claim 1, wherein the binder has a glass transition temperature and the temperature provided by the applied heat is in a range of 5-200° C. above the glass transition temperature of the binder.

3. The process according to claim 2, wherein the temperature provided by the applied heat is in a range of 50-120° C. above the glass transition temperature of the binder.

4. The process according to claim 1, wherein the temperature provided by the applied heat is in a range of ±30° C. of a melting temperature of the binder.

5. The process according to claim 1, wherein the pressure applied to the conductive ink track is in a range of 10-2000 psi.

6. The process according to claim 1, wherein the heat and pressure are applied at least once for a duration of time in a range of 0.01-5 seconds.

7. The process according to claim 1, wherein the heat and pressure are applied in at least two pulses spaced apart in time to permit the substrate to cool.

8. The process according to claim 1, wherein the conductive particles comprise flakes.

9. The process according to claim 1, wherein the conductive particles comprise conductive metal particles.

10. The process according to claim 1, wherein the conductive particles comprise silver.

11. The process according to claim 1, wherein the conductive ink track is densified by the applied heat and pressure, and the conductive ink track is provided with increased electrical conductivity, increased thermal conductivity, increased strength, increased bonding performance to external attachments or any combination thereof.

12. The process according to claim 1, wherein the substrate is flatter after the process than before the process.

13. The process according to claim 1, wherein the heat and pressure are applied with a flat-bed press, the flat-bed press comprising a hot press half in contact with the first surface of the substrate and a cold press half in contact with the second surface of the substrate.

14. The process according to claim 1, wherein the heat and pressure are applied with a pair of press rolls, the pair of press rolls comprising a hot roll in contact with the first surface of the substrate and a cold roll in contact with the second surface of the substrate.

15. The process according to claim 1, wherein the conductive ink track forms an electrical circuit, a sensor or an antenna on the substrate.

16. A printed electronic device produced by the process of claim 1.
